(19) United States
(12) Patent Application Publication
(10) Pub. No.: US 2024/0063033 A1
(43) Pub. Date: Feb. 22, 2024

(54) SUBSTRATE HEATING DEVICE CONFIGURED TO SUPPRESS CRACK GENERATION

(71) Applicant: MiCo Ceramics Ltd., Anseong-si (KR)

(72) Inventor: Hyosung PARK, Anseong-si (KR)

(21) Appl. No.: 18/451,195

(22) Filed: Aug. 17, 2023

(30) Foreign Application Priority Data
Aug. 18, 2022 (KR) 10-2022-0103557

(51) Int. Cl. H01L 21/67; H01L 21/687; H01R 4/58

(52) U.S. Cl. CPC H01L 21/67098; H01L 21/68714; H01R 4/58; H01L 2221/683

(57) ABSTRACT

The present disclosure relates to a substrate heating device capable of effectively suppressing the generation of cracks. The substrate heating device including: a body having a substrate seating element on which a substrate is seated, thereby supporting the substrate; a first heating element positioned in an inner area of the body; a second heating element positioned in an outer area surrounding the inner area of the body; a power transfer wire configured to transfer a current to the second heating element across the inner area of the body; a heater connector configured to supply a current to the power transfer wire; and a connector connecting element connected from the heater connector to the power transfer wire, wherein the connector connecting element is made of molybdenum-tungsten alloy including molybdenum and tungsten.

### CROSS-REFERENCE TO RELATED APPLICATION

This application is based on and claims priority under 35 U.S.C. 119 to Korean Patent Application No. 10-2022-0103557, filed on Aug. 8, 2022, in the Korean Intellectual Property Office, the disclosure of which is herein incorporated by reference in its entirety.

### FIELD OF THE INVENTION

The present disclosure relates to a substrate heating device and, more particularly, to a substrate heating device capable of effectively suppressing the generation of cracks on the periphery of a wire connected to a heater connector for supplying an electric current to a heater in the substrate heating device.

### BACKGROUND

In general, a flat display panel or a semiconductor element is manufactured through a process in which a series of layers including a dielectric layer and a metal layer are successively laminated on a substrate (for example, a glass substrate, a flexible substrate, or a semiconductor substrate) and are then patterned. The series of layers including a dielectric layer and a metal layer are deposited onto the substrate by a process such as chemical vapor deposition (CVD) or physical vapor deposition (PVD).

The substrate needs to be heated at a constant temperature in order to form the layers evenly, and a substrate heating device may be used to heat and support the substrate. The substrate heating device may be used to heat the substrate during a process in which the dielectric layer or metal layer formed on the substrate is etched, or during a photoresistor sintering process.

Furthermore, there has been a continued demand for a scheme for reducing the temperature deviation of the substrate heating device in line with recent trends toward micro-wiring of semiconductor elements and requirements for precise heat treatment of semiconductor substrates. Particularly, a supporting element is positioned in the center area of the substrate heating device so as to support the body made of ceramic or the like, in which a heater is contained, thereby increasing the heat capacity. This may pose a problem in that, even if the same amount of heat is applied to each area of the substrate heating device, a temperature deviation may occur in each area.

In this regard, it has been proposed to divide the substrate heating device, as illustrated in FIG. 1, into an inner area (area B in FIG. 1) and an outer area (area C in FIG. 1) such that, by controlling substrate heating in each area, the temperature deviation between the inner area (area B in FIG. 1) and the outer area (area C in FIG. 1) can be reduced.

Furthermore, the body of the substrate heating device is commonly made of ceramic such as aluminum nitride (AlN), while the heater and the like are made of a metal such as molybdenum (Mo). During processes for manufacturing the substrate heating device, the heater and the like are disposed in a predetermined position inside the body made of ceramic such as aluminum nitride (AlN), and the ceramic is sintered while applying a high pressure in a high-temperature (for example, about 1800° C.) environment, thereby configuring the body.

However, during the sintering process in which a high pressure is applied in a high-temperature environment, the difference in coefficient of thermal expansion (CTE) between the ceramic that constitutes the body and the metal material of the heater induces thermal stress, and the high pressure induces compressive stress, thereby generating cracks in the ceramic of the body. Moreover, the cracks may be dispersed by using the substrate heating device, thereby degrading the durability of the substrate heating device and shortening the lifespan thereof.

Particularly, as illustrated in FIG. 2A and FIG. 2B, it has been confirmed that the cracks are generated in a concentrated manner by a metal wire connected to a heater connector positioned inside the shaft at the center of the ceramic substrate heating device (as indicated by (A) in FIG. 2B, ultrasonic nondestructive testing can confirm the position in which cracks are generated, as indicated by shading). In addition, as illustrated in FIG. 3, it can be confirmed that cracks ((A) in FIG. 3) generated in the metal wire can propagate to the RF mesh layer positioned below the same ((B) and (C) in FIG. 3).

Therefore, there is a need for a scheme for suppressing the occurrence of thermal stress due to a difference in coefficient of thermal expansion between the ceramic that constitutes the body and the metal material of the wire for constituting the heater during a sintering process and the like, in which a high temperature and a high pressure are applied, among the processes for manufacturing the substrate heating device, and suppressing the occurrence of compressive stress due to the applied high pressure, thereby preventing the body from cracking, and effectively preventing degradation of the durability of the substrate heating device and shortening of the lifespan. However, no appropriate solution has been provided in this regard.

### SUMMARY

The present disclosure has been made to solve the above-mentioned problems occurring in the prior art, and it is an aspect of the present disclosure to provide a substrate heating device capable of effectively suppressing the occurrence of cracks due to thermal stress resulting from a difference in coefficient of thermal expansion between the ceramic material of the body and the metal material of the wire connected to the heater connector during a sintering process and the like, in which a high temperature and a high pressure are applied, among the processes for manufacturing the substrate heating device, and compressive stress resulting from the applied high pressure.

It is another aspect of the present disclosure to provide a substrate heating device capable of effectively preventing degradation of the durability of the substrate heating device and shortening of the lifespan due to dispersion of cracks generated by using the substrate heating device.

In accordance with an aspect of the present disclosure, a substrate heating device may include: a body having a substrate seating element on which a substrate is seated, thereby supporting the substrate; a first heating element positioned in an inner area of the body; a second heating element positioned in an outer area surrounding the inner area of the body; a power transfer wire configured to transfer a current to the second heating element across the inner area of the body; a heater connector configured to supply a current to the power transfer wire; and a connector connecting element connected from the heater connector to the power transfer wire, wherein the connector connecting element is made of molybdenum-tungsten alloy including molybdenum and tungsten.

The substrate heating device may further include a connecting member configured to electrically connect the power transfer wire and the connector connecting element.

The connecting member may be made of molybdenum-tungsten alloy including molybdenum and tungsten.

The connector connecting element may be made of a wire having a diameter smaller than the diameter of the power transfer wire.

The connecting member may be implemented in a cylindrical shape having openings provided at both longitudinal ends of the cylindrical shape so as to face each other such that the connector connecting element and the power transfer wire are inserted and fixed therein, respectively.

The molybdenum-tungsten alloy may include 40-80% of molybdenum and 20-60% of tungsten.

The body may be made of aluminum nitride (AlN).

At least one of the heater connector or the power transfer wire may be made of molybdenum metal.

A substrate heating device according to an embodiment of the present disclosure is advantageous in that it is possible to effectively suppress the occurrence of cracks due to thermal stress resulting from a difference in coefficient of thermal expansion between the ceramic material of the body and the metal material of the wire connected to the heater connector during a sintering process and the like, in which a high temperature and a high pressure are applied, among the processes for manufacturing the substrate heating device, and compressive stress resulting from the applied high pressure.

In addition, a substrate heating device according to an embodiment of the present disclosure is advantageous in that it is possible to effectively prevent degradation of the durability of the substrate heating device and shortening of the lifespan due to dispersion of cracks generated by using the substrate heating device.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a top view of a substrate heating device according to the prior art;

FIG. 2A to FIG. 3 illustrate cracks generated in the substrate heating device according to the prior art;

FIG. 4A to FIG. 6B illustrate the structure of a substrate heating device according to an embodiment of the present disclosure;

FIG. 7 illustrates the configuration of a substrate heating device according to an embodiment of the present disclosure;

FIG. 8 to FIG. 10 illustrate the configuration and operation of a substrate heating device according to an embodiment of the present disclosure; and

FIG. 11A to FIG. 13 illustrate the characteristics of molybdenum-tungsten alloy in a substrate heating device according to an embodiment of the present disclosure.

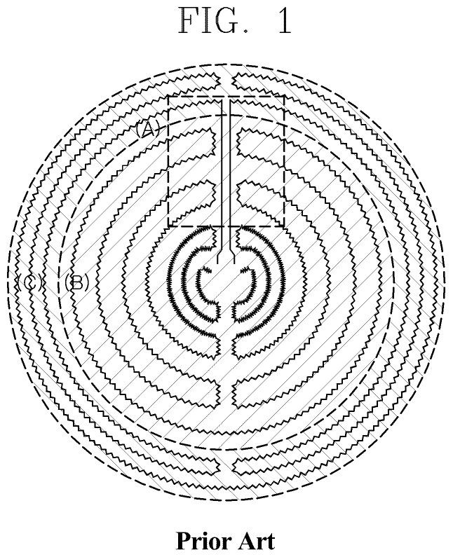

### DETAILED DESCRIPTION OF THE EXEMPLARY EMBODIMENTS

The present disclosure may be variously modified and may have various embodiments. Hereinafter, the present disclosure will be described in detail with reference to the accompanying drawings.

In the following description of the present disclosure, detailed descriptions regarding relevant known technologies will be omitted if deemed to be likely to obscure the gist of the present disclosure.

Terms such as first and second may be used to describe various components, but the components are not limited by such terms, which are used only to distinguish the components from each other.

Hereinafter, exemplary embodiments of a substrate heating device according to the present disclosure will be described in detail with reference to the accompanying drawings.

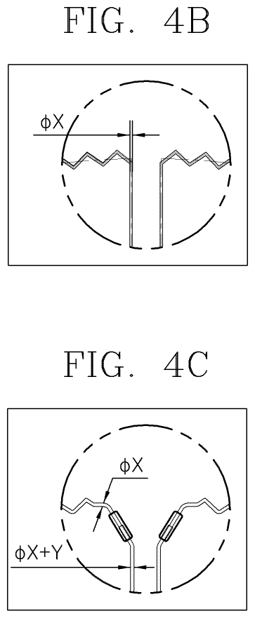

FIG. 4A to FIG. 4C illustrate the structure 300 of a substrate heating device according to an embodiment of the present disclosure. As illustrated in FIG. 4A to FIG. 4C, the substrate heating device 300 according to an embodiment of the present disclosure may include a body (not illustrated) configured to support a substrate, a first heating element 310 positioned in an inner area of the body, a second heating element 320 positioned in an outer area which surrounds the inner area, and a power transfer wire 330 configured to transfer an electric current to the second heating element 320 across the inner area of the body. The power transfer wire 330 may have a diameter larger than the diameter of the wire that constitutes the second heating element 320, thereby decreasing the resistance value of the power transfer wire 330. Accordingly, heat generation in the power transfer wire 330 may be suppressed, thereby preventing a specific area from being overheated by heat generated by the power transfer wire 330.

A substrate (for example, a glass substrate, a flexible substrate, or a semiconductor substrate) is seated on the substrate heating device 300 and undergoes a process such as chemical vapor deposition (CVD) or physical vapor deposition (PVD) such that a series of layers including a dielectric layer and a metal layer are deposited thereon and then patterned. The substrate heating device 300 evenly heats the substrate at a temperature required by the process.

The body (not illustrated) of the substrate heating device 300 may be made of ceramic, metal, or the like according to the usage or process. The body may include a heater for heating the substrate together with a high-frequency electrode (not illustrated) used for a plasma process or the like. In addition, the substrate heating device 300 may have multiple pin holes (not illustrated) formed such that lift pins can move so as to seat a substrate onto the upper surface of the body or to unload the same to the outside.

The body of the substrate heating device 300 may be made of a ceramic material for the sake of stability or the like during the high-temperature process. Ceramic available in this regard may be Al₂O₃, Y₂O₃, Al₂O₃/Y₂O₃, ZrO₂, AlC, TiN, AlN, TiC, MgO, CaO, CeO₂, TiO₂, BₓC_{y}, BN, SiO₂, SiC, YAG, Mullite, AlF₃, or the like. A combination of two or more of the above ceramics may be used.

The first heating element 310 and the second heating element 320 may be made of tungsten (W), molybdenum (Mo), silver (Ag), gold (Au), platinum (Pt), niobium (Nb), titanium (Ti), or an alloy thereof.

As illustrated in FIG. 4B, the second heating element 320 and the power transfer wire 330 may be made of a single wire having the same diameter. However, such a conventional configuration may have a problem in that, if power is applied to the second heating element 320 in the outer area so as to generate heat, the power transfer wire 330 generates heat in the same manner as the second heating element 320, and the middle area in which the power transfer wire 330 may be overheated.

Particularly, the amount of heat generated by the power transfer wire 330, combined with heat generated by the first heating element 310 near the middle area, may further overheat middle area. This may cause a problem in that thermal uniformity is substantially degraded by overheating of a specific area.

In this regard, it may be considered to position the first heating element 310 away from the power transfer wire 330 in order to reduce the influence of heat generated by the first heating element 310. However, in such a case, the amount of heat generated in the middle area in which the power transfer wire 330 is positioned may greatly differ from the amount of heat generated in a symmetric area which has symmetry with the middle area with reference to the center point of the body, depending on the state in which power is applied to each area. As a result, the thermal uniformity of the substrate heating device may rather be degraded in some cases.

Therefore, the structure of the first heating element 310 in the middle area and the structure of the first heating element 310 in the symmetric area corresponding thereto preferably constitute the same symmetric structure if possible, and are preferably configured in a structure as similar much as possible even if the symmetric structure cannot be configured because the power transfer wire 330 needs to be installed, for example.

Therefore, it is more preferred to reduce the amount of heat generated in the power transfer wire 330 while maintaining the symmetric structure of the first heating element 310 to the maximum extent. Accordingly, in the present disclosure, as illustrated in FIG. 4C, the diameter (X+Y) of the wire that constitutes the power transfer wire 330 is preferably configured to be larger than the diameter (X) of the wire that constitutes the second heating element 320 such that the resistance value is reduced, thereby suppressing heat generated by the power transfer wire 330.

In addition, the first heating element 310 is preferably not positioned in the middle area in which the power transfer wire 330 is positioned in the substrate heating device 300 according to an embodiment of the present disclosure such that the first heating element 310 and the power transfer wire 330 are spaced apart from each other without overlapping each other, thereby reducing the effect of overlapping between heat generated by the first heating element 310 and heat generated by the power transfer wire 330.

Furthermore, the substrate heating device 300 according to an embodiment of the present disclosure is not necessarily configured to have two divided areas (inner area and outer area) as illustrated in FIG. 4A, and may be configured to include multiple areas, including the inner and outer areas and one or more additional areas.

In addition, with reference to the center axis of the middle area extending through the center point of the body, the first heating element 310, the second heating element 320, and the power transfer wire 330 may be configured in symmetric shapes such that the substrate heating device 300 according to an embodiment of the present disclosure has a symmetric heat distribution with reference to the center axis, and the thermal uniformity of the substrate heating device 300 is further improved.

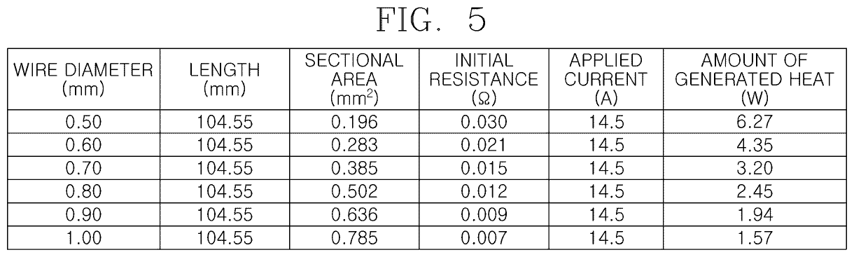

Moreover, FIG. 5 illustrates a table in which changes in the resistance value and the amount of heat generation are calculated and compared while varying the diameter of the power transfer wire 330 according to an embodiment of the present disclosure. It is clear from FIG. 5 that, if the diameter of the power transfer wire 330 is 0.50 mm, the resistance value is 0.030 Ohm, and if an electric current of 14.5 A is applied to the wire, the amount of heat generated by the wire is 6.27 W.

In contrast, if the diameter of the power transfer wire 330 is 1.00 mm, the resistance value of the wire is 0.007 Ohm, and if an electric current of 14.5 A is applied to the wire, the amount of heat generated by the wire is 1.57 W. It is clear therefrom that, as the wire diameter doubles from 0.50 mm to 1.00 mm, each of the resistance value and the amount of heat generation becomes about ¼.

Similarly, it is clear that, as the diameter of the power transfer wire 330 increases from 0.5 mm to 0.70 mm (about 1.4 times), each of the resistance value and the amount of heat generation becomes about ½.

Therefore, the amount of heat generated by the power transfer wire 330 can be reduced by increasing the diameter of the power transfer wire 330. In addition, since the diameter of the power transfer wire 330 cannot be increased indefinitely, the amount of heat generated in the middle area in which the power transfer wire 330 is positioned is preferably adjusted so as to be close to the amount of heat generated in other areas in view of the diameter of the power transfer wire 330, the distance of spacing between a pair of power transfer wires 330, heat generated by the first heating element 310, and the like.

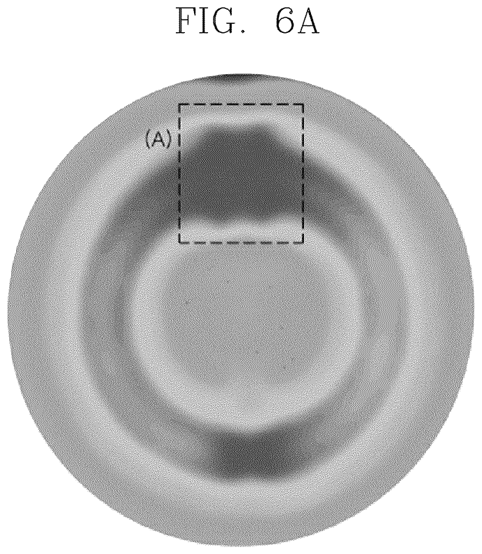

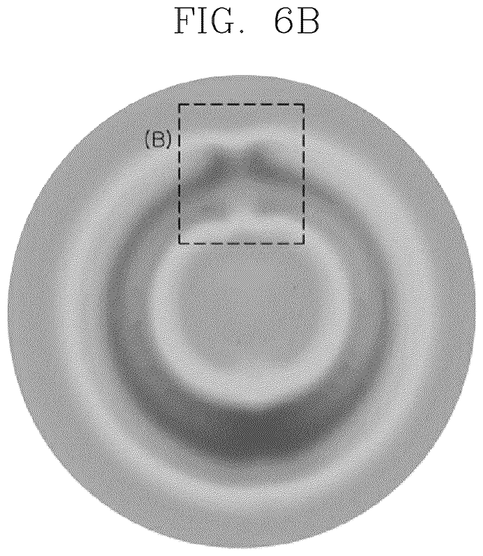

Thereafter, FIG. 6A and FIG. 6B illustrate a case in which overheating in a specific area of the substrate heating device 300 according to an embodiment of the present disclosure is suppressed, thereby improving thermal uniformity. It is clear from FIG. 6A that, if heating by the power transfer wire 330 in the middle area fails to be suppressed adequately, the amount of heat generation may concentrate in the middle area (overheating). However, it is clear from FIG. 6B that, in the case of the substrate heating device 300 according to an embodiment of the present disclosure, the diameter of the power transfer wire 330 is larger than the wire that constitutes the second heating element 320 such that, by lowering the resistance value of the power transfer wire 330 and suppressing heat generated by the power transfer wire 330, the occurrence of overheating in the middle area can be effectively suppressed.

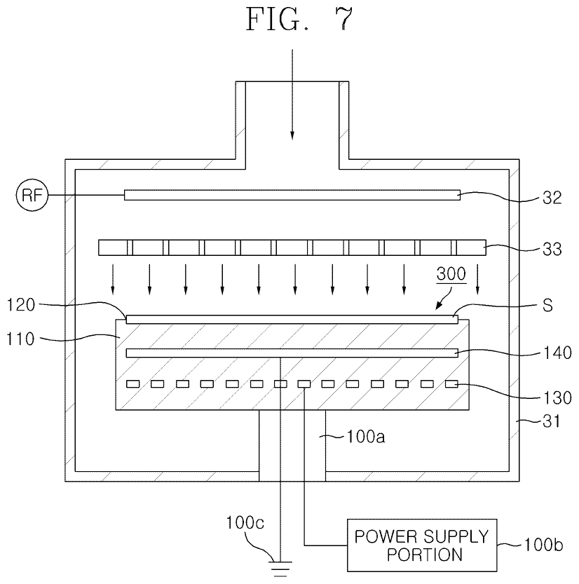

In addition, FIG. 7 illustrates a more detailed structure of the substrate heating device 300 according to an embodiment of the present disclosure. As illustrated in FIG. 7, the substrate heating device 300 according to an embodiment of the present disclosure is configured to heat a substrate S and may include a body 110 having a substrate seating element 120 on which a substrate S is seated, thereby supporting the substrate S, and a heating element 130 embedded in the lower portion of the body 110 so as to heat the substrate S. The heating element 130 may include a first heating element 310 positioned in an inner area of the body 110, a second heating element 320 positioned in an outer area which surrounds the inner area, and a power transfer wire 330 configured to transfer an electric current to the second heating element 320 across the inner area of the body 110.

Moreover, as illustrated in FIG. 7, the substrate heating device 300 according to an embodiment of the present disclosure may include a supporting element 110a configured to support the body 110, a power supply element 100b configured to supply power to the heating element 130, and a grounding element 100c configured to provide grounding, and may further include a high-frequency electrode 140 to which high-frequency waves are applied to form plasma.

Furthermore, as illustrated in FIG. 7, the substrate heating device 300 according to an embodiment of the present disclosure may be disposed inside a chamber 31 such that a process is performed, and the chamber 31 may include a plasma electrode 32, a shower head 33, and the like.

However, the first heating element 310, the second heating element 320, and the power transfer wire 330 of the substrate heating device 300 are conventionally made of a metal, while the body 110 of the substrate heating device 300 is conventionally made of ceramic such as aluminum nitride (AlN).

During processes for manufacturing the substrate heating device 300, the first heating element 310, the second heating element 320, and the power transfer wire 330 are disposed in predetermined positions inside the body 110 made of aluminum nitride (AlN) or the like, and the ceramic is sintered while applying a high pressure in a high-temperature (for example, about 1800° C.) environment, thereby manufacturing the substrate heating device 300.

During the sintering process in which a high pressure is applied in a high-temperature environment, the difference in coefficient of thermal expansion (CTE) between the ceramic that constitutes the body 110 and the metal material of the heaters and the like may induce thermal stress, and the high pressure may induce compressive stress, thereby generating cracks in the ceramic area of the body 110.

Furthermore, dispersion of the cracks caused by using the substrate heating device 300 may degrade the durability of the substrate heating device 300 and shorten the lifespan.

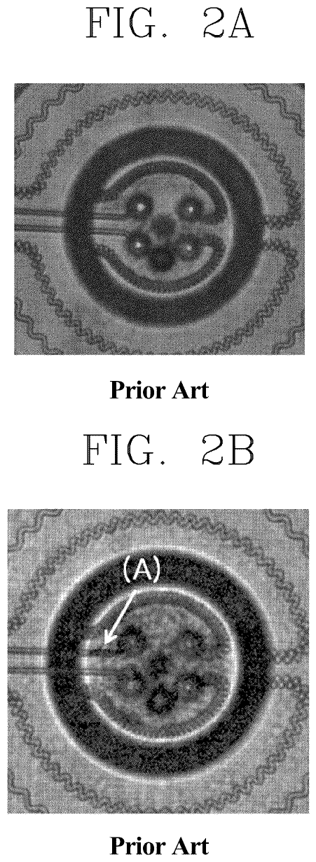

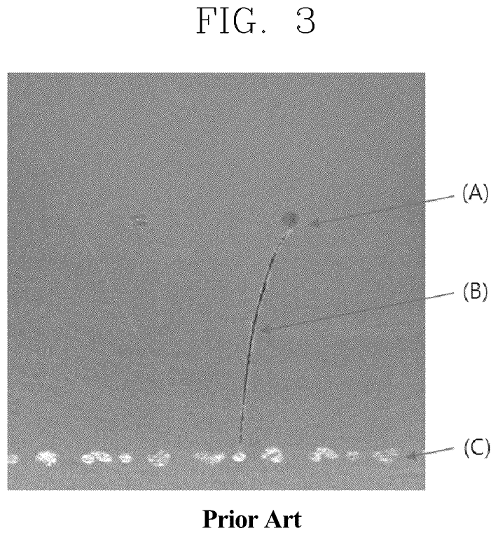

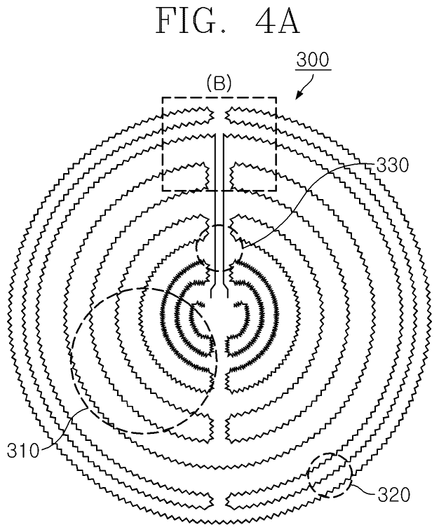

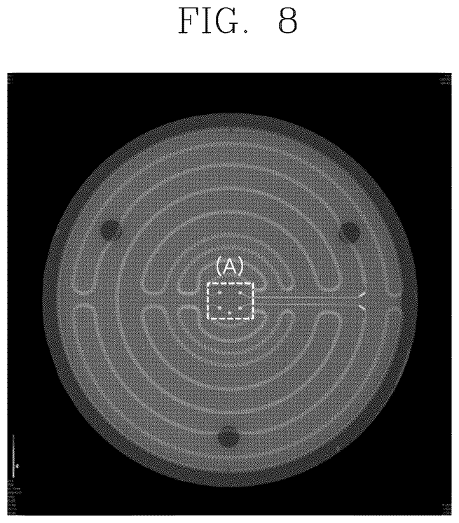

Particularly, as described above with reference to FIG. 2, present inventors have confirmed that the cracks may be generated in a concentrated manner by the metal wire connected to the heater connector 340 positioned inside the shaft (area (A) in FIG. 8) at the center of the ceramic substrate heating device.

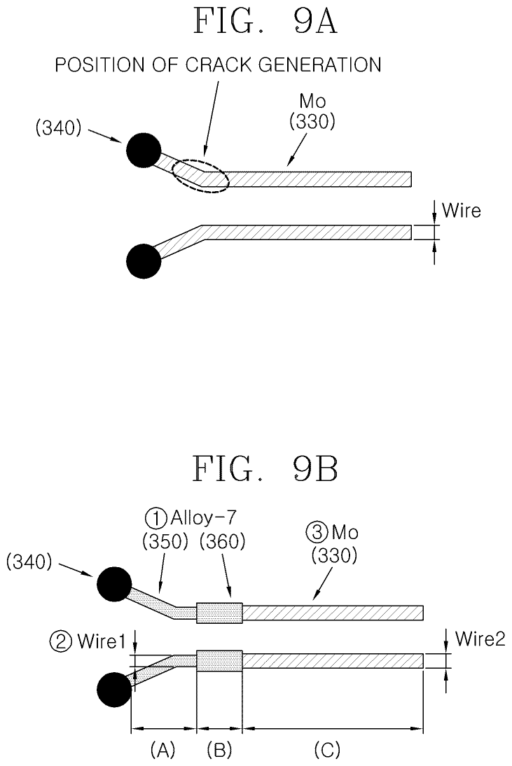

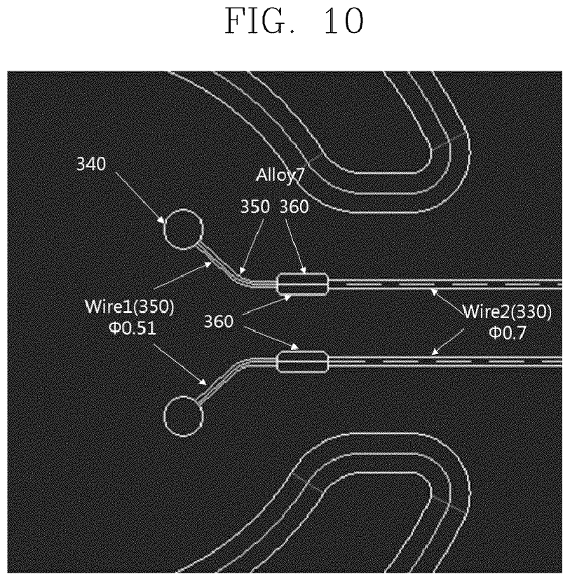

More specifically, as illustrated in FIG. 9A, in the case of a conventional substrate heating device 300, cracks may be generated in a concentrated manner in the area in which the heater connector 340 and the power transfer wire 330 are connected, and the cracks may be dispersed by using the substrate heating device 300, thereby degrading the durability of the substrate heating device 300 and shortening the lifespan.

In contrast, as illustrated in FIG. 9B, the substrate heating device 300 according to an embodiment of the present disclosure has a connector connecting element 350 configured from the heater connector 340 to the power transfer wire 330 and made of molybdenum-tungsten alloy including molybdenum and tungsten, thereby effectively suppressing cracks which would otherwise occur in a concentrated manner in the area in which the heater connector 340 and the power transfer wire 330 are connected.

That is, the power transfer wire 330 of the conventional substrate heating device 300 is commonly made of a metal such as molybdenum (Mo), while the body 110 of the substrate heating device 300 is commonly made of ceramic such as aluminum nitride (AlN). Accordingly, during processes for manufacturing the substrate heating device 300, the first heating element 310, the second heating element 320, the power transfer wire 330, the heater connector 340, and the like are disposed in predetermined positions in advance inside the body 110 made of ceramic such as aluminum nitride (AlN), and the ceramic is sintered while applying a high pressure in a high-temperature (for example, about 1800° C.) environment, thereby manufacturing the substrate heating device 300.

However, during the sintering process in which a high pressure is applied in a high-temperature environment, the difference in coefficient of thermal expansion (CTE) between the ceramic that constitutes the body 110 and the metal material of the power transfer wire 330 may induce thermal stress, thereby generating cracks in the area of the body 110 in which the heater connector 340 and the power transfer wire 330 are connected.

Moreover, accumulated exposure to the process temperature (for example, 650° C.) of the substrate heating device 300 may disperse the cracks, thereby degrading the durability of the substrate heating device 300 and shortening the lifespan.

In this regard, the substrate heating device 300 according to an embodiment of the present disclosure has a connector connecting element 350 connected from the heater connector 340 to the power transfer wire 330 and made of molybdenum-tungsten alloy including molybdenum and tungsten. Accordingly, thermal stress due to a difference in coefficient of thermal expansion (CTE) with the ceramic material (for example, aluminum nitride (AlN)) that constitutes the body 110 is prevented, thereby effectively suppressing cracks.

Furthermore, as illustrated in FIG. 9B, the substrate heating device 300 according to an embodiment of the present disclosure may have a connecting member 360 configured to electrically connect the power transfer wire 330 and the connector connecting element 350.

The connecting member 360 may also be made of molybdenum-tungsten alloy including molybdenum and tungsten.

The connecting member 360 may be implemented in a cylindrical shape having openings provided at both longitudinal ends of the cylindrical shape so as to face each other such that the connector connecting element 350 and the power transfer wire 330 are inserted and fixed therein, respectively.

The connector connecting element 350 and the power transfer wire 330 may be fixed into the openings of the connecting member 360 through press-fitting.

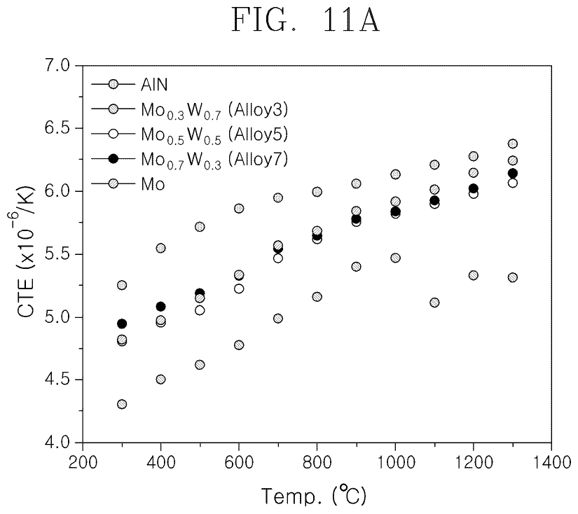

Moreover, as illustrated in FIG. 10, the substrate heating device 300 according to an embodiment of the present disclosure may have a connector connecting element 350 made of a wire having a smaller diameter than that of the power transfer wire 330.

More specifically, as described above, during the sintering process in which a high pressure is applied in a high-temperature environment, among processes for manufacturing the substrate heating device 300, the difference in coefficient of thermal expansion (CTE) between the ceramic that constitutes the body 110 and the metal wire may induce thermal stress, and the high pressure may induce compressive stress, thereby generating cracks in the ceramic area of the body 110. Therefore, the connector connecting element 350 of the substrate heating device 300 according to an embodiment of the present disclosure has a reduced diameter such that the influence of stress caused by the high pressure applied during the sintering process is reduced, thereby suppressing the occurrence of cracks.

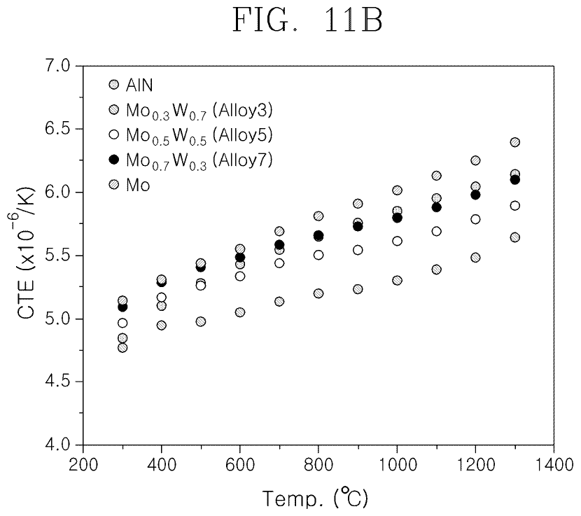

FIG. 11A and FIG. 11B show a comparison of the coefficient of thermal expansion (CTE) of the metal material (for example, molybdenum-tungsten alloy) that constitutes the connector connecting element 350 and that of the ceramic material (AlN) (FIG. 11A shows the CTE during a temperature increase, and FIG. 11B shows the CTE during a temperature decrease).

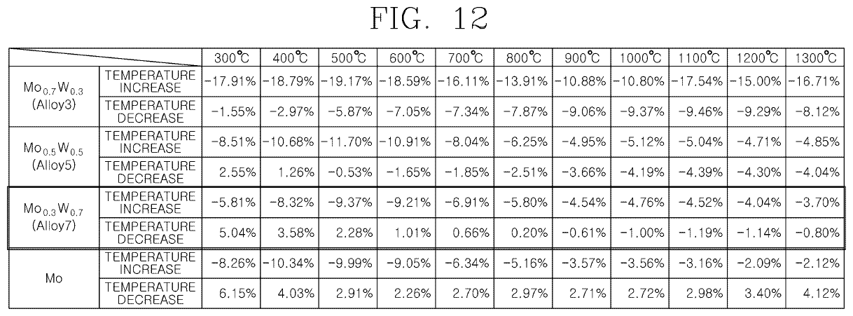

FIG. 12 illustrates a table enumerating numeric values of the difference of the coefficient of thermal expansion of the metal material (for example, molybdenum-tungsten alloy) that constitutes the connector connecting element 350 with reference to the coefficient of thermal expansion of the ceramic material.

It is clear from FIG. 11A, FIG. 12B, and FIG. 12 that, compared with the coefficient of thermal expansion (H65) of the ceramic material, the coefficient of thermal expansion of molybdenum 70%/tungsten 30% alloy (Mo_{0.7}W_{0.3}, Alloy7) is closest to the coefficient of thermal expansion of the ceramic material.

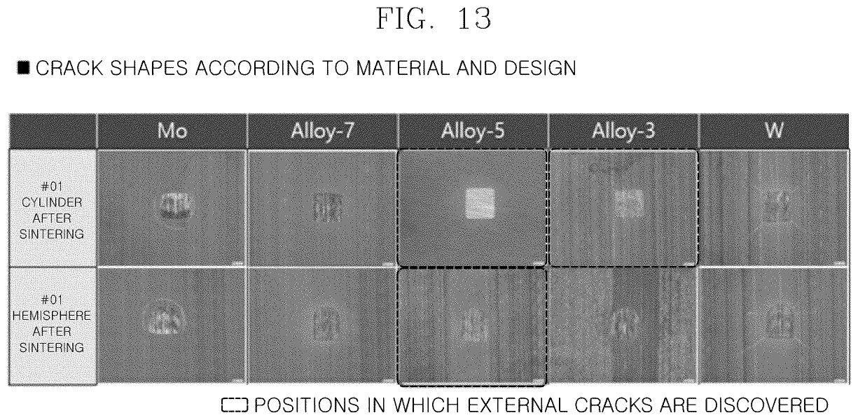

In this regard, FIG. 13 illustrates the result of experiment regarding the occurrence of cracks according to the type of metal material (for example, molybdenum-tungsten alloy) that constitutes the connector connecting element 350.

Firstly, the heater connector was configured by using molybdenum (Mb), molybdenum-tungsten alloy (Mo_{0.3}W_{0.7}(Alloy3), Mo_{0.5}W_{0.5}(Alloy5), Mo_{0.7}W_{0.3}(Alloy7)), and tungsten (W) with regard to a case in which the heater connector has a cylindrical shape and a case in which a hemisphere is added to an end thereof, respectively.

FIG. 13 shows the result of confirming whether cracks are generated in the ceramic sintered body after a sintering process. It is clear from FIG. 13 that, if the heater connector is made of molybdenum (Mb) or tungsten (W), multiple cracks are generated in the ceramic sintered body. It is also clear therefrom that, if the heater connector is made of molybdenum 30%/tungsten 70% alloy (Mo_{0.3}W_{0.7}, Alloy3) and molybdenum 50%/tungsten 50% alloy (Mo_{0.5}W_{0.5}, Alloy5), some cracks are generated in the ceramic sintered body.

In contrast, it is clear that, if the heater connector is made of molybdenum 70%/tungsten 30% alloy (Mo_{0.7}W_{0.3}, Alloy7), no cracks are generated in the ceramic sintered body.

Therefore, it is clear that the connector connecting element 350 of the substrate heating device 300 according to an embodiment of the present disclosure is preferably made of molybdenum-tungsten alloy including molybdenum and tungsten, and if the molybdenum-tungsten alloy includes 60-80% of molybdenum and 20-40% of tungsten, no cracks are generated in the ceramic sintered body of the body 110 even after undergoing a sintering pressure at a high temperature and a high pressure.

Therefore, the substrate heating device 300 according to an embodiment of the present disclosure suppresses the occurrence of thermal stress due to a difference in coefficient of thermal expansion between the ceramic material of the body 110 and the metal material of the connecting member 360 and the like during a sintering process and the like, in which a high temperature and a high pressure are applied, among the processes for manufacturing the substrate heating device 300, and suppresses the occurrence of compressive stress due to the applied high pressure, thereby preventing the ceramic material of the body 110 from cracking, and effectively preventing degradation of the durability of the substrate heating device 300 and shortening of the lifespan.

In addition, one or at least two of metallic members, including the heater connector 340 or the power transfer wire 330, of the substrate heating device 300 according to an embodiment of the present disclosure may be made of molybdenum, thereby minimizing impedance change and performance degradation of the substrate heating device 300 resulting from metal material characteristic changes, and suppressing the generation of cracks.

Furthermore, the connecting member 360 of the substrate heating device 300 according to an embodiment of the present disclosure may also be made of molybdenum-tungsten alloy including molybdenum and tungsten, and the molybdenum-tungsten alloy of the connecting member 360 may include 60-80% of molybdenum and 20-40% of tungsten as in the case of the connector connecting element 350, thereby effectively preventing generation of cracks in the ceramic sintered body of the body 110 even after going through a sintering process at a high temperature and a high pressure.

Therefore, the substrate heating device 300 according to an embodiment of the present disclosure suppresses the occurrence of thermal stress due to a difference in coefficient of thermal expansion between the ceramic material of the body 110 and the metal material of the wire connected to the connecting member 360 during a sintering process and the like, in which a high temperature and a high pressure are applied, among the processes for manufacturing the substrate heating device 300, and suppresses the occurrence of compressive stress due to the applied high pressure. In addition, it is possible to effectively prevent degradation of the durability of the substrate heating device 300 and shortening of the lifespan resulting from cracks dispersed by using the substrate heating device 300.

Although the technical idea of present disclosure has been described in exemplary manners, those skilled in the art to which the present disclosure pertains could make various changes and modifications without deviating from the essential characteristics of the present disclosure. Therefore, embodiments described herein are not intended to limit, but to describe the technical idea of present disclosure, which is not limited to such embodiments. The scope of protection of the present disclosure is to be interpreted by the appended claims, and all technical ideas falling within equivalent ranges are to be interpreted as being included in the scope of protection of the present disclosure.

### BRIEF DESCRIPTION OF REFERENCE NUMERALS

31: chamber
32: plasma electrode
33: shower head
100a: supporting element
100b: power supply element
100c: grounding element
110: body
120: substrate seating element
130: heating element
140: high-frequency electrode
300: substrate heating device
310: first heating element
320: second heating element
330: power transfer wire
340: heater connector
350: connector connecting element
360: connecting member
S: substrate

What is claimed is:

1. A substrate heating device comprising:
a body having a substrate seating element on which a substrate is seated, thereby supporting the substrate;
a first heating element positioned in an inner area of the body;
a second heating element positioned in an outer area surrounding the inner area of the body;
a power transfer wire configured to transfer a current to the second heating element across the inner area of the body;
a heater connector configured to supply a current to the power transfer wire; and
a connector connecting element connected from the heater connector to the power transfer wire,
wherein the connector connecting element is made of molybdenum-tungsten alloy comprising molybdenum and tungsten.

2. The substrate heating device of claim 1, further comprising a connecting member configured to electrically connect the power transfer wire and the connector connecting element.

3. The substrate heating device of claim 2, wherein the connecting member is made of molybdenum-tungsten alloy comprising molybdenum and tungsten.

4. The substrate heating device of claim 1, wherein the connector connecting element is made of a wire having a diameter smaller than the diameter of the power transfer wire.

5. The substrate heating device of claim 2, wherein the connecting member is implemented in a cylindrical shape having openings provided at both longitudinal ends of the cylindrical shape so as to face each other such that the connector connecting element and the power transfer wire are inserted and fixed therein, respectively.

6. The substrate heating device of claim 1, wherein the molybdenum-tungsten alloy comprises 60-80% of molybdenum and 20-40% of tungsten.

7. The substrate heating device of claim 1, wherein the body is made of aluminum nitride (AlN).

8. The substrate heating device of claim 1, wherein at least one of the heater connector or the power transfer wire is made of molybdenum metal.
